(19) United States
(12) Patent Application Publication
(10) Pub. No.: US 2026/0179890 A1
(43) Pub. Date: Jun. 25, 2026

(54) CONTAMINANT REMOVAL DEVICE FOR ARC REACTION CHAMBER AND METHOD THEREOF

(71) Applicant: Taiwan Semiconductor Manufacturing Company, Ltd., Hsinchu (TW)

(72) Inventor: Lung-Yin Tang, Hsinchu (TW)

(73) Assignee: Taiwan Semiconductor Manufacturing Company, Ltd., Hsinchu (TW)

(21) Appl. No.: 19/000,158

(22) Filed: Dec. 23, 2024

(51) Int. Cl. H01J 37/32

(52) U.S. Cl. CPC H01J 37/32871; H01J 37/32055

(57) ABSTRACT

A contaminant removal device for an arc reaction chamber is provided. The contaminant removal device includes an impact generating device and a driver. The impact generating device is disposed on one side of the arc reaction chamber, and the driver is coupled to the impact generating device. The driver is used to provide a force to drive the impact generating device to move toward the arc reaction chamber.

### BACKGROUND

Ion implantation systems or ion implanters are widely used to dope semiconductors with impurities in integrated circuit manufacturing, as well as in the manufacture of flat panel displays. In such systems, an ion source ionizes a desired dopant element, which is extracted from the source in the form of an ion beam of desired energy. The ion beam is then directed at the surface of the workpiece, such as a semiconductor wafer, in order to implant the workpiece with the dopant element. The ions of the beam penetrate the surface of the workpiece to form a region of desired conductivity, such as in the fabrication of transistor devices in the wafer. The implantation process is typically performed in a high vacuum process chamber, which prevents dispersion of the ion beam by collisions with residual gas molecules and minimizes the risk of contamination of the workpiece by airborne particles. A typical ion implanter includes an ion source for generating the ion beam, a beamline including a mass analysis magnet for mass resolving the ion beam, and a target chamber containing the semiconductor wafer or other substrate or workpiece to be implanted by the ion beam, although flat panel display implanters typically do not include a mass analysis apparatus. For high energy implantation systems, an acceleration apparatus may be provided between the mass analysis magnet and the target chamber for accelerating the ions to high energies.

Conventional ion sources include a plasma confinement chamber (called as arc chamber) having an inlet aperture for introducing a gas to be ionized into plasma and an exit aperture opening through which the plasma is extracted to form the ion beam. One example of a dopant gas is phosphine. When phosphine is exposed to an energy source, such as energetic electrons or radio frequency (RF) energy, the phosphine can disassociate to form positively charged phosphorous (P+) ions for doping the workpiece, as well as disassociated hydrogen ions. Typically, phosphine is introduced into the plasma confinement chamber and then exposed to the electron source to produce both phosphorous ions and hydrogen ions. The plasma comprises ions desirable for implantation into a workpiece, as well as undesirable ions which are a by-product of the dissociation and ionization processes. The phosphorous ions and the hydrogen ions are then extracted through the exit opening into the ion beam using an extractor including energized extraction electrodes. Examples of other typical dopant elements of which the source gas is comprised include phosphorous (P), arsenic (As), or Boron (B), and many others.

However, since the flow direction of the reaction gas passes below the anti-cathode, in addition to being taken out from the extractor, the reactive ions are easily deposited on the anti-cathode and the side plate to form contaminants, and finally cause peeling phenomenon. Sometimes, this deposition phenomenon even causes a short circuit between the anti-cathode and the side plate, causing the entire ion source device to fail and become unusable. Equipment maintenance personnel must often dismantle the ion source device for replacement or cleaning. This will affect actual yield and increase a lot of manpower and material costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of an ion source device according to an embodiment of the present disclosure.

FIG. 2 is a schematic diagram of a contaminant removal device for an arc reaction chamber according to an embodiment of the present disclosure.

FIG. 3 is a schematic diagram of the impact head knocking the chamber holder in FIG. 2 and shows a schematic diagram of contaminant peeling.

FIG. 4 is an exploded schematic diagram of a contaminant removal device for the arc reaction chamber in FIG. 2.

FIG. 5 is a schematic diagram of a contaminant removal device for the arc reaction chamber according to an embodiment of the present disclosure.

FIGS. 6 to 9 respectively illustrate schematic diagrams of contaminant removal devices for the arc reaction chamber according to different embodiments.

FIG. 10 is a flow chart illustrating various steps of a method for removing contaminants in an arc reaction chamber according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Generally speaking, an ion implanter mainly includes an ion source device that generates ions, a mass analyzer that separates dopant ions, and an accelerator that accelerates ion implantation. Among them, the ion source device mainly includes a vacuum container, a holder body, an evaporator, an arc chamber, etc., and the arc chamber is a direct-current (DC) plasma generator. After the arc reaction chamber in the ion source device generates ions, the required ions can be implanted into the wafer through the action of the mass analyzer and accelerator.

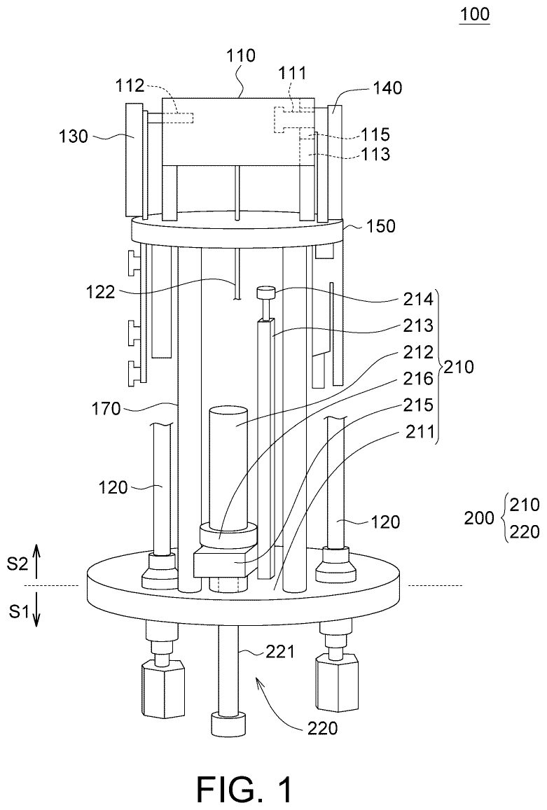

Referring to FIG. 1, FIG. 1 is a schematic diagram of an ion source device 100 according to an embodiment of the present disclosure. In a general commercial ion implanter, the arc reaction chamber 110 of the ion source device 100 has an anti-cathode 111 and a hot filament 112 that can generate thermionic electrons. Direct current heating is used to generate thermionic electrons on the surface of the filament 112 to increase the frequency of collisions between electrons and input gas molecules, thereby increasing the concentration of ions.

The ion implanters are not only bulky and complex in structure, but generally the ion implanters used in processes with lower doping doses are medium-current ion implanters, the current value is about 1 mA, and the implantation dose is about 10¹¹ to 10¹³ ions/cm²; while the higher dose process uses a high-current ion implanter, the current value is about 10 to 20 mA, and the implantation dose is about 10¹⁴ to 10¹⁶ ions/cm².

The main function of the ion source device 100 is to generate ions to provide N-type or P-type impurities required for the process. If N-type ions are to be formed, PH₃ gas, for example, can be added, and if P-type ions are to be formed, BF₃ gas, for example, can be added. In the ion source device 100, the reaction gas enters through the gas inlet, passes through the gas delivery pipes 120 and 122, and then reaches the arc reaction chamber 110 above. General delivery pipes 120 and 122 are shown in the figures. There is a simple conveying pipeline 122 in the middle, and there are delivery pipes 120 with evaporation chambers on both sides. When the dopant used is a solid material, the gas delivery pipes 120 with an evaporation chamber can be used with a higher temperature to increase the saturated vapor pressure of solid doping, so as to increase the concentration of gas molecules and make the ion source easy to generate the required ions.

The hot filament 112 that can generate thermionic electrons is provided at one end of the arc reaction chamber 110. The hot filament 112 is fixed with a filament clamp 130 and can be made of metals, such as tungsten, tantalum, or molybdenum. After direct current is used to heat the filament 112, thermionic electrons are released from the surface of the filament 112 and collide with the input gas to generate ions. Depending on the type of filament 112, a Bernas type or Freeman type arc reaction chamber 110 may be used.

In addition, the anti-cathode 111 is placed at the other end of the arc reaction chamber 110. The anti-cathode 111 is fixed by the anti-cathode clamp 140, and a negative bias is provided to the anti-cathode 111 to prevent thermionic electrons or ions from gathering on one side of the arc reaction chamber 110 and increase the reaction probability. As the number of thermionic electrons increases, the collisions with gas molecules will also increase. Some examples of the arc reaction chamber 110 also add magnets (not shown in the figure) to increase the frequency of collisions.

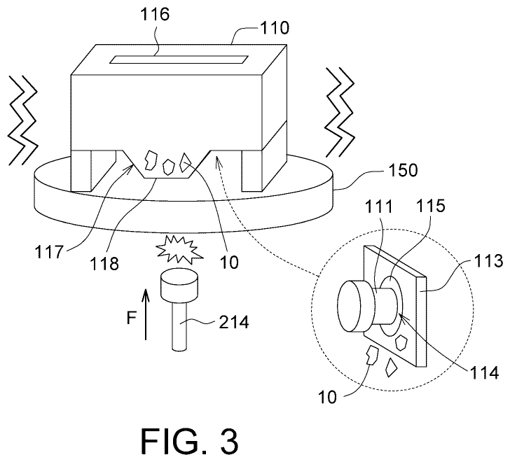

In the ion source device 100, the flow path of the reaction gas first flows to the bottom of the arc reaction chamber 110, and then enters the arc reaction chamber 110 through the anti-cathode side plate 113 at one side of the arc reaction chamber 110. The round hole 114 in the middle of the anti-cathode side plate 113 is a place where the anti-cathode 111 is disposed (see FIG. 3), the bottom of the anti-cathode side plate 113 has an inlet (not shown), and the dopant gas and carrier gas can pass through the inlet or any entrance at other locations and enters the arc reaction chamber 110. When the reaction gas seeps out in large amounts through the bottom of the anti-cathode 111, the filament 112 of the arc reaction chamber 110 will generate thermal ionization electrons that react with the input gas to generate ions. After the charged ions in the arc reaction chamber 110 are formed, the ions can be extracted from the extraction pores 116 in the top plate of the reaction chamber through appropriate bias voltage, thus achieving the purpose of generating ions from the ion source.

As shown in FIG. 3, the anti-cathode side plate 113 is made of graphite. In order to avoid the risk of electrical short circuit, the round hole 114 is usually surrounded by an insulating layer 115. In order to avoid the short circuit caused by the products deposited on the anti-cathode side plate 113 and the anti-cathode 111 being in contact with each other, this embodiment uses the impact generating device 210 to vibrate the arc reaction chamber 110 to remove the products that is peeled off from the inner walls in the arc reaction chamber 110 and concentrated at the bottom 118 of the chamber. In this way, excessive products deposited in the arc reaction chamber 110 can be removed.

Referring to FIG. 1, the contaminant removal device 200 for the arc reaction chamber 110 includes an impact generating device 210 and a driver 220. The impact generating device 210 is disposed on one side of the arc reaction chamber 110, and the driver 220 is connected to or magnetically coupled to the impact generating device 210. The driver 220 is used to provide a force to drive the impact generating device 210 to move toward the arc reaction chamber 110.

The impact generating device 210 includes a holder body 211, a movable rod 213, an impact head (i.e., bumper) 214 and a slider 215. The impact head 214 is disposed at one end (e.g., the top end) of the movable rod 213, and the slider 215 is disposed at the other end (e.g., the bottom end) of the movable rod 213. The impact head 214 is used to knock a component of the ion source device 100 (such as the arc reaction chamber 110 or the holder for mounting the arc reaction chamber 110 (hereinafter referred to as the chamber holder 150), so that the arc reaction chamber 110 is forced to vibrate. The slider 215 is, for example, sleeved on a hollow tube 212 stood on the holder body 211, and the slider 215 can move back and forth along an axis on the hollow tube 212, so that the movable rod 213 generates a displacement relative to the arc reaction chamber 110 or the chamber holder 150. In one embodiment, the displacement of the movable rod 213 is less than the axial length of the hollow tube 212. In addition, the impact head 214 can be of any shape or structure, and the stroke of the impact head 214 can be adjusted according to needs.

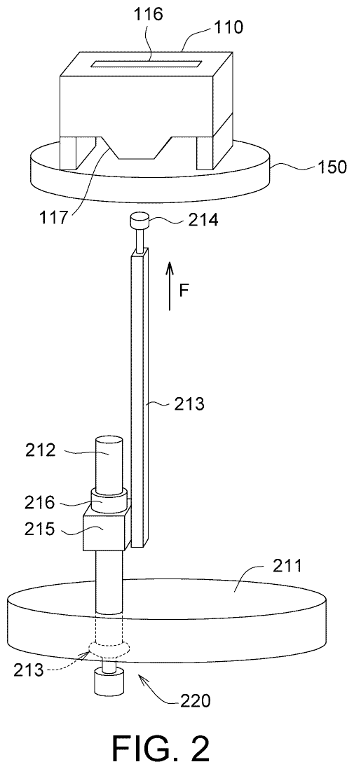

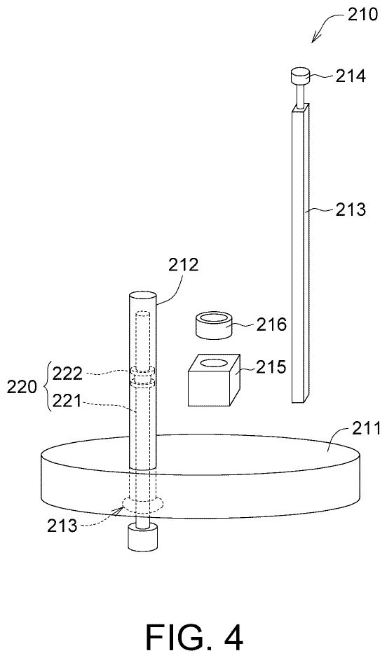

Referring to FIGS. 2, 3 and 4, FIG. 2 illustrates a schematic diagram of a contaminant removal device 200 for the arc reaction chamber 110 according to an embodiment of the present disclosure, and FIG. 3 illustrates a schematic diagram of the impact head 214 knocking the chamber holder 150 in FIG. 2 and shows a schematic diagram of the contaminant 10 peeling off. FIG. 4 shows an exploded schematic diagram of a contaminant removal device 200 for the arc reaction chamber 110 in FIG. 2.

As shown in FIG. 2, the holder body 211 is used to isolate the external atmosphere from the vacuum inside the ion source, so that the inside of the ion source is sealed and maintained in a predetermined vacuum state. The impact generating device 210 is disposed inside the ion source, that is, between the chamber holder 150 and the holder body 211, so that the impact generating device 210 can operate in a vacuum state. The holder body 211 includes a plurality of fixed posts 170 for supporting the chamber holder 150 and the arc reaction chamber 110. In one embodiment, the impact generating device 210 can be actuated by a magnetic force F to generate an impact force, for example, a magnet 216 is provided on the slider 215 and a magnet 222 (refer to FIG. 4) is provided on a shaft 221 of the driver 220, and the magnetic conductor 216 and the magnet 222 can generate magnetic force to attract each other.

As shown in FIGS. 2 and 4, the impact generating device 210 is disposed on the inner side S2 of the holder body 211, that is, on the vacuum side of the ion source device 100; and the driver 220 is disposed on the outer side S1 of the holder body 211, that is, on the atmospheric side of the ion source device 100. The shaft 221 of the driver 220 can extend from the outside of the holder body 211 to the inside of the holder body 211 through the through hole 213 of the holder body 211, so that the shaft 221 of the driver 220 is accommodated in the hollow tube 212. In addition, the inside of the hollow tube 212 is in communication with the outside atmosphere, but not in communication with the inside of the ion source device 100, so as to keep the inside of the ion source device 100 in a vacuum state. In addition, the magnet 222 is disposed in the hollow tube 212, and the magnet 222 can be sleeved on the shaft 221. The magnet 222 can be driven by the shaft 221 to move back and forth in the hollow tube 212. As can be seen from the above description, the driver 220 is used to provide a force F to drive the impact generating device 210 to move toward the arc reaction chamber 110. In addition to the magnetic force described in this embodiment, the present disclosure can also use a driver 220 such as an electromagnetic device, a pneumatic device, and a hydraulic device to generate the force F, and is not limited thereto.

As shown in FIG. 3, the arc reaction chamber 110 has a reservoir 117 located at the bottom 118 of the chamber. When the arc reaction chamber 110 is knocked by the impact head 214 and vibrates, the reservoir 117 can concentrate the products or contaminants 10 that fall off at the bottom 118 of the chamber. Maintenance personnel can replace the reservoir 117 regularly or irregularly to remove the products or contaminants 10 in the reservoir 117. In one embodiment, the reservoir 117 is, for example, funnel-shaped. The reservoir 117 can be configured as a movable or detachable type, and is fixed to the bottom 118 of the chamber by means of buckles. This detachable configuration can facilitate maintenance personnel to replace and install the reservoir 117 on the chamber.

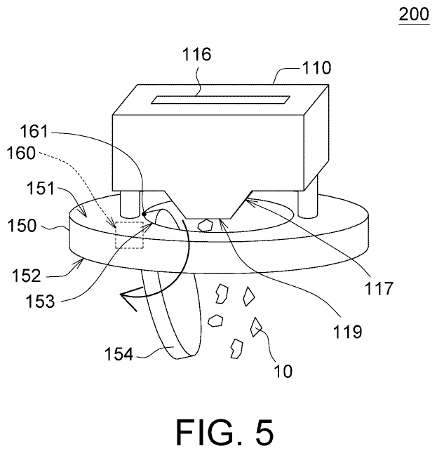

Referring to FIG. 5, FIG. 5 is a schematic diagram of a contaminant removal device 200 for the arc reaction chamber 110 according to another embodiment of the present disclosure. In this embodiment, the arc reaction chamber 110 has a reservoir 117 at the bottom, and the reservoir 117 has an outlet 119 at the bottom. The products or contaminants 10 in the reservoir 117 can be discharged from the arc reaction chamber 110 through the outlet 119. In addition, in order to facilitate the removal of products or contaminants 10 in the reservoir 117, the contaminant removal device 200 may also include a chamber holder 150 and a movable plate 154. The chamber holder 150 is disposed on one side of the arc reaction chamber 110. The chamber holder 150 has a first surface 151, a second surface 152 and an opening 153. The first surface 151 and the second surface 152 are located on opposite sides of the chamber holder 150, and the opening 153 penetrates the first surface 151 and the second surface 152. The movable plate 154 is pivotally connected to the chamber holder 150 so that the movable plate 154 can rotate relative to the opening 153. When the movable plate 154 is in a closed state, the movable plate 154 closes the outlet 119 located at the bottom of the reservoir 117 to concentrate the products or contaminants 10 in the reservoir 117; and when the movable plate 154 is in an open state, the outlet 119 located at the bottom of the reservoir 117 is exposed to allow the products or contaminants 10 in the reservoir 117 to be discharged through the outlet 119 and the opening 153 so that the products or contaminants 10 can be thrown away. In this way, the contaminant removal device 200 of this embodiment can be implemented without affecting actual mass production, thus reducing a lot of manpower and material costs.

In one embodiment, the movable plate 154 includes a steering device 160. The steering device 160 has, for example, a gear set (not shown), a rotating shaft 161 and a motor (not shown). The rotating shaft 161 and the gear set are coaxially arranged at the pivot joint between the movable plate 154 and the chamber holder 150. The motor is, for example, an electric motor or a stepper motor. The motor is disposed on one side of the chamber holder 150 and is connected to the rotating shaft 161 and the gear set to drive the movable plate 154 to rotate relative to the opening 153. In addition, the steering device 160 is not limited to using a motor to drive the movable plate 154. The present disclosure can also be implemented by using other power sources such as electromagnetic devices, pneumatic devices, and hydraulic devices to generate power.

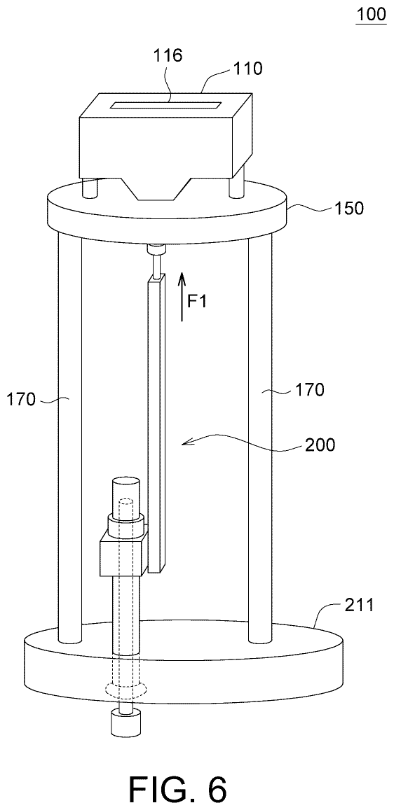

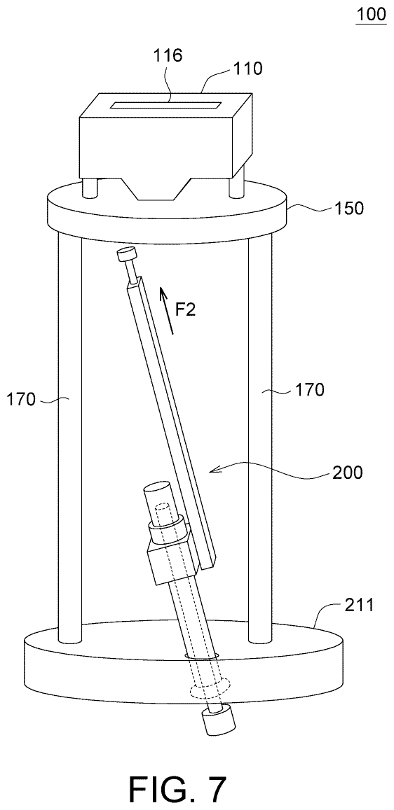

Referring to FIGS. 6 to 9, schematic diagrams of contaminant removal devices 200 for the arc reaction chamber 110 according to various embodiments are respectively illustrated. In FIG. 6, the contaminant removal device 200 is, for example, vertically disposed on a bottom side of the arc reaction chamber 110, and provides a positive force F1 upward from directly below the chamber holder 150 to the chamber holder 150 so as to cause the arc reaction chamber 110 to vibrate. In FIG. 7, for example, the contaminant removal device 200 is disposed obliquely on the bottom side of the arc reaction chamber 110, and provides an oblique force F2 upward from directly below the chamber holder 150 to the chamber holder 150 so as to cause the arc reaction chamber 110 to vibrate. The angle of the oblique force F2 relative to the normal direction of the chamber holder 150 is about 5 degrees to 85 degrees, such as 20 degrees to 40 degrees or other suitable angles.

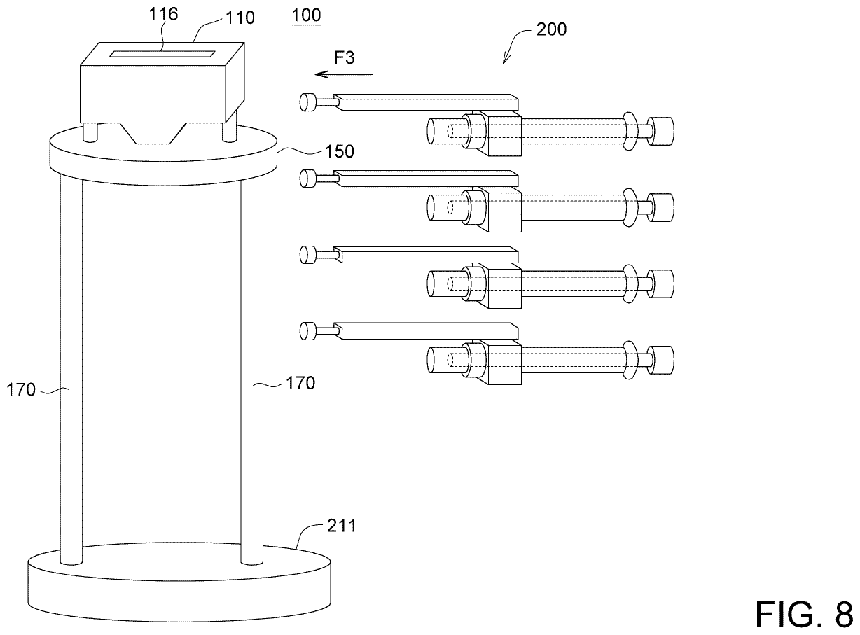

In FIG. 8, the contaminant removal device 200 is, for example, disposed on one side of the arc reaction chamber 110, which provides a lateral force F3 from the side of the arc reaction chamber 110 to at least one component inside the ion source device 100 (such as the chamber holder 150, the arc reaction chamber 110 or other components) to cause the arc reaction chamber 110 to vibrate. In the embodiment, the number of the contaminant removal device 200 is not limited to only one, and multiple contamination removal devices 200 can be disposed on the side of the arc reaction chamber 110. Although not shown in the figure, it is conceivable that the side wall of the holder body 211 can extend upward to the side of the arc reaction chamber 110 to fix each of the contaminant removal devices 200 on the side wall of the holder body 211.

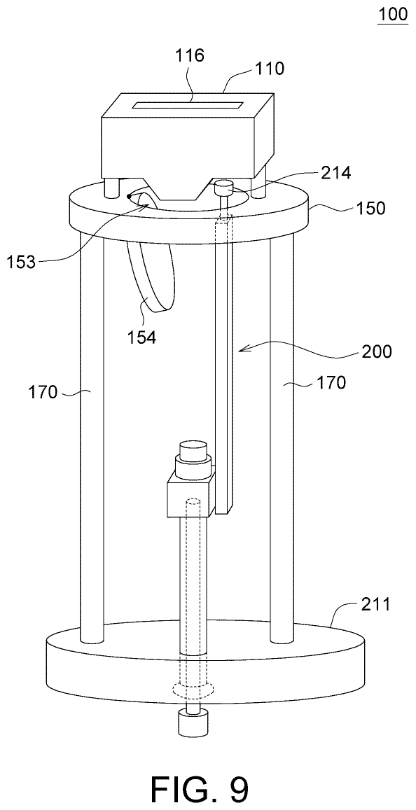

In FIG. 9, the chamber holder 150 has an opening 153 and a movable plate 154, and the contaminant removal device 200 is disposed on a bottom side of the movable plate 154, for example. When the movable plate 154 is in the open state, the impact head 214 can extend to the arc reaction chamber 110 through the opening 153 of the chamber holder 150 and knock the bottom of the arc reaction chamber 110 to cause the arc reaction chamber 110 to vibrate. In addition, after the products or contaminants 10 are removed, the impact head 214 can move and retract below the opening 153 of the chamber holder 150, and at this time, the movable plate 154 can be closed to cover the opening 153.

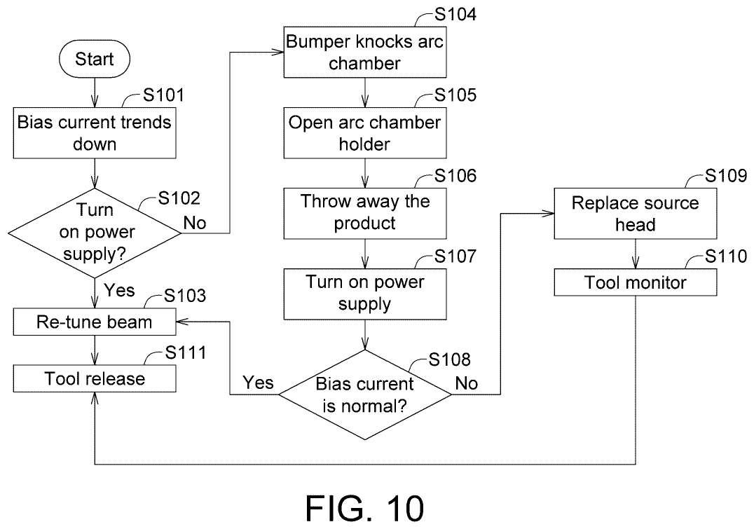

Referring to FIG. 10, a flow chart illustrating various steps of a method for removing contaminants in an arc reaction chamber 110 according to an embodiment of the present disclosure is disclosed. In step S101, an appropriate time is selected to remove the product. For example, when the bias current provided to the anti-cathode 111 trends down, it means that the product deposited on the anti-cathode side plate 113 and the anti-cathode 111 come into contact with each other and cause a short circuit, and therefore sufficient bias voltage cannot be provided to the anti-cathode 111. In step S102, when it is confirmed that the power supply of the ion source device 100 can be turned on, the step S130 is performed to re-tune the ion source device 100 to generate an ion beam. In step S102, when it is confirmed that the power of the ion source device 100 cannot be turned on smoothly, in step S104, the impact head 214 is used to knock the arc reaction chamber 110 to cause the arc reaction chamber 110 to vibrate. The number of times of knocking the arc reaction chamber 110 may be one or more times until the power supply of the ion source device 100 can be turned on (as shown in step S107). In step S108, whether the bias current is normal or returns to normal is confirmed. When the bias current is normal, step S103 is performed to re-tune the ion source device 100 to generate an ion beam. In step S108, if the bias current is still abnormal, indicating that the products or contaminants 10 deposited on the anti-cathode side plate 113 cannot be effectively removed and cause the arc reaction chamber 110 to fail, then the step S109 is performed to replace the ion source device 100. Next, in step S110, the replaced new ion source device 100 is monitored to determine that the arc reaction chamber 110 operates normally. Finally, in step S111, the monitoring tool is released.

In some embodiments, when using the contaminant removal device 200 with the movable plate 154 shown in FIG. 5, the above-described contaminant removal method may also include the following steps S105 and S106. In step S105, the arc reaction chamber 110 uses the reservoir 117 to collect the products or contaminants 10, and then opens the movable plate 154. In step S106, the products or contaminants 10 in the reservoir 117 can be discharged through the outlet 119 at the bottom of the reservoir 117 and pass through the opening 153 to throw away the products or contaminants 10.

The impact generating device described in the embodiment is used to knock the arc reaction chamber to peel off the products or contaminants in the arc reaction chamber from the inner wall of the chamber and concentrate them at the bottom of the chamber. In this way, excessive products or contaminants deposited in the arc reaction chamber can be removed to avoid failure of the arc reaction chamber.

The present disclosure relates to a contaminant removal device for an arc reaction chamber and a method thereof. One of the main features of the present disclosure is to use an impact generating device to knock the arc reaction chamber to peel off the products deposited in the arc reaction chamber from the inner wall of the chamber and concentrate them at the bottom of the chamber. In this way, the products or contaminants deposited in the arc reaction chamber can be removed. This deposition phenomenon may even cause a short circuit between the anti-cathode and the anti-cathode side plate. Therefore, the contaminant removal device of the present disclosure can avoid conventional short circuit and reduce labor replacement and maintenance costs, thereby improving the reliability of the arc reaction chamber.

According to some embodiments of the present disclosure, a contaminant removal device for an arc reaction chamber is provided, which includes an impact generating device and a driver. The impact generating device is disposed on one side of the arc reaction chamber, and the driver is coupled to the impact generating device. The driver is used to provide a force to drive the impact generating device to move toward the arc reaction chamber.

According to some embodiments of the present disclosure, a contaminant removal device for an arc reaction chamber is provided, which includes a chamber holder and a movable plate. The chamber holder is disposed on one side of the arc reaction chamber. The chamber holder has a first surface, a second surface and an opening. The first surface and the second surface are located on opposite sides of the chamber holder, and the opening penetrates the first surface and the second surface. The movable plate is pivotally connected to the chamber holder, so that the movable plate is rotatable relative to the opening.

According to some embodiments of the present disclosure, a contaminant removal method for an arc reaction chamber is provided, including the following steps. An impact generating device is arranged on one side of the arc reaction chamber. A force is provided to the impact generating device to drive the impact generating device to move toward the arc reaction chamber. The force causes the contaminants in the arc reaction chamber to peel off and fall down to a reservoir of the arc reaction chamber, and the reservoir is used to collect the contaminants.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A contaminant removal device for an arc reaction chamber, comprising:
an impact generating device arranged on one side of the arc reaction chamber; and
a driver coupled to the impact generating device, and the driver being used to provide a force to drive the impact generating device to move toward the arc reaction chamber.

2. The contaminant removal device of claim 1, wherein the impact generating device comprises an impact head for knocking the arc reaction chamber or a chamber holder for mounting the arc reaction chamber.

3. The contaminant removal device of claim 2, wherein the impact generating device further comprises a movable rod and a slider, the movable rod is disposed on the slider, and the impact head is disposed on one end of the movable rod.

4. The contaminant removal device of claim 3, wherein the impact generating device further comprises a holder body and a hollow tube, the hollow tube is disposed on one side of the holder body, the slider is sleeved on the hollow tube and is movable along an axial direction of the hollow tube.

5. The contaminant removal device of claim 4, wherein the driver is disposed on another side of the holder body, the driver comprises a shaft, the shaft is accommodated in the hollow tube, the shaft extends from one side of the holder body to the other side of the holder body via a through hole passing through the holder body.

6. The contaminant removal device of claim 5, wherein the driver further comprises a magnet, the impact generating device further comprises a magnet conductor, the magnet conductor is disposed on the slider, and the magnet is disposed on the shaft, the magnetic conductor and the magnet generate a magnetic force that attracts each other.

7. The contaminant removal device of claim 1, wherein a bottom of the arc reaction chamber comprises a reservoir, and the impact generating device is used to knock the arc reaction chamber so that the contaminants peel off and fall down in the reservoir.

8. The contaminant removal device of claim 7, wherein the reservoir is configured as a movable or detachable type.

9. The contaminant removal device of claim 7, further comprising a chamber holder and a movable plate, the arc reaction chamber is disposed on the chamber holder, the chamber holder has an opening, and the movable plate is pivotally connected to the chamber holder so that the movable plate is rotatable relative to the opening.

10. A contaminant removal device for an arc reaction chamber, comprising:
a chamber holder arranged on one side of the arc reaction chamber, the chamber holder has a first surface, a second surface and an opening, wherein the first surface and the second surface are located on opposite sides of the chamber holder, and the opening penetrates the first surface and the second surface; and
a movable plate pivotally connected to the chamber holder so that the movable plate is rotatable relative to the opening.

11. The contaminant removal device of claim 10, further comprising an impact generating device disposed on one side of the arc reaction chamber, the impact generating device comprising an impact head for knocking the arc reaction chamber or a chamber holder for mounting the arc reaction chamber.

12. The contaminant removal device of claim 11, wherein the impact generating device further comprises a movable rod and a slider, the movable rod is disposed on the slider, and the impact head is disposed on one end of the movable rod.

13. The contaminant removal device of claim 12, wherein the impact generating device further comprises a holder body and a hollow tube, the hollow tube is disposed on one side of the holder body, the slider is sleeved on the hollow tube and is movable along an axial direction of the hollow tube.

14. The contaminant removal device of claim 13, further comprising a driver disposed on another side of the holder body, the driver comprising a shaft, the shaft being accommodated in the hollow tube, the shaft extends from one side of the holder body to the other side of the holder body via a through hole of the holder body.

15. The contaminant removal device of claim 14, wherein the driver further comprises a magnet, the impact generating device further comprises a magnetic conductor, the magnetic conductor is disposed on the slider, and the magnet is disposed on the shaft, the magnetic conductor and the magnet generate a magnetic force that attracts each other, and the driver uses the magnetic force to drive the impact generating device to move toward the arc reaction chamber.

16. A method for removing contaminants in an arc reaction chamber, comprising:
providing an impact generating device on one side of the arc reaction chamber;
providing a force to the impact generating device to drive the impact generating device to move toward the arc reaction chamber; and
causing the contaminants in the arc reaction chamber to peel off and fall down to a reservoir of the arc reaction chamber by the force, and the reservoir is used to collect the contaminants.

17. The contaminant removal method of claim 16, wherein the reservoir is configured as a movable or detachable type.

18. The method of removing contaminants of claim 16, wherein the arc reaction chamber is disposed on a chamber holder, the chamber holder has an opening and a movable plate, and the movable plate is pivotally connected to the chamber holder so that the movable plate is rotatable relative to the opening.

19. The method of removing contaminants of claim 18, wherein after the contaminants in the arc reaction chamber fall down to the reservoir, the method of removing contaminants further comprises opening the movable plate to throw away the contaminations from the opening.

20. The method of removing contaminants of claim 18, wherein after the contaminants are thrown away, the method of removing contaminants further comprises closing the opening by the movable plate.
